(19) United States
(12) Patent Application Publication
(10) Pub. No.: US 2009/0208637 A1
(43) Pub. Date: Aug. 20, 2009

(54) COBALT PRECURSORS USEFUL FOR FORMING COBALT-CONTAINING FILMS ON SUBSTRATES

(75) Inventors: Tianniu Chen, Rocky Hill, CT (US); Chongying Xu, New Milford, CT (US); Jeffrey F. Roeder, Brookfield, CT (US); Thomas H. Baum, New Fairfield, CT (US); Bryan C. Hendrix, Danbury, CT (US)

Correspondence Address: INTELLECTUAL PROPERTY / TECHNOLOGY LAW, PO BOX 14329, RESEARCH TRIANGLE PARK, NC, 27709, US

(73) Assignee: ADVANCED TECHNOLOGY MATERIALS, INC., Danbury, CT (US)

(21) Appl. No.: 12/305,000

(22) PCT Filed: Jun. 13, 2007
(86) PCT No.: PCT/US07/71153

§ 371 Date: Jan. 9, 2009

(30) Foreign Application Priority Data
Jun. 15, 2006 (US) 60813968

(51) Int. Cl. C23C 16/18; C07F 15/06; C07F 5/02; B05D 5/12

(52) U.S. Cl. 427/78; 556/36; 546/10; 556/8; 556/140; 556/40; 106/1.27

(57) ABSTRACT

Cobalt precursors for forming metallic cobalt thin films in the manufacture of semiconductor devices, and methods of depositing the cobalt precursors on substrates, e.g., using chemical vapor deposition or atomic layer deposition processes. Packaged cobalt precursor compositions, and microelectronic device manufacturing systems are also described.

### CROSS-REFERENCE TO RELATED APPLICATIONS

This application claims the benefit of priority of U.S. Provisional Patent Application No. 60/813,968 filed on Jun. 15, 2006 under 35 USC 119.

### FIELD OF THE INVENTION

The present invention relates generally to novel cobalt compounds, their synthesis, and to methods of depositing said novel cobalt complexes on microelectronic device structures.

### DESCRIPTION OF THE RELATED ART

Semiconductor integrated circuit (IC) chip fabrication technology has focused on techniques and materials to produce smaller and faster devices with increasing packing densities for higher performance chips. This trend towards miniaturization has led to demand for improved semiconductor IC interconnect performance and improved manufacturability, resulting in a shift from conventional Al/SiO₂ interconnect architectures to copper-based metallization in conjunction with low-permittivity (or low-k) dielectrics. Compared to aluminum, copper metallization reduces interconnect propagation delays, reduces cross-talk, and enables higher interconnect current densities with extended electro-migration lifetime.

Most notable among the integrated circuit (IC) metallization processes that use copper is damascene processing. It involves the formation of inlaid trenches and vias in an interlevel dielectric (ILD) or some other insulating layer, followed by the deposition of a conformal barrier layer that blocks diffusion of copper atoms into the ILD. A wide range of barrier materials is conventionally utilized, including materials comprising metals, metal nitrides, metal silicides, and metal silicon nitrides. Illustrative barrier materials include titanium nitride, titanium silicide, tantalum nitride, tantalum silicide, tantalum silicon nitrides, titanium silicon nitrides, niobium nitrides, niobium silicon nitrides, tungsten nitride, tungsten silicide, and ruthenium. For some of these barrier materials, such as tantalum nitride, an intermediate layer, such as tantalum metal, is added for adhesion. Thereafter, the desired copper conductive wires and plugs in the trenches and vias are formed by first depositing a copper seed layer, which provides a conformal, conductive layer, and then electrofilling the features with a thicker layer of copper.

PVD has traditionally been used to form the seed layer, but does not always provide conformal step coverage, particularly with surface features having high aspect ratios (greater than about 5:1). Chemical vapor deposition (CVD) is another process by which the seed layer may be deposited, however, poor nucleation of the copper at the barrier layer is a common problem with CVD, as is agglomeration. These problems result, in part, because copper itself does not adhere well to most materials, including tantalum nitride and other materials conventionally employed as diffusion barriers.

Another problem with copper deposition CVD processes arises from the utilization of fluorine-containing precursor compounds, which can cause interfacial contamination, thus further deteriorating the adhesion of the copper layer to the underlying barrier layer or intermediate adhesion layer. This can lead to reliability problems, such as when subsequent stress-inducing steps such as chemical mechanical polishing (CMP) are carried out, or in subsequent use of the resulting microelectronic product, as result of the electromigration.

Another technique for ultra-thin film deposition that is rapidly growing in application in the semiconductor manufacturing industry is atomic layer deposition (ALD). In this process, the precursor is chemisorbed onto a substrate to form a ‘monolayer’ of precursor. A second reagent species is then similarly introduced to chemically react with the first chemisorbed layer to grow the desired film onto the substrate surface.

To improve the adhesion of copper to the barrier layer, and thus utilize bottom-up filling techniques, an intermediate layer with good adhesion and barrier properties may be deposited prior to any copper metallization. This intermediate layer may include, for example, metals, metal nitrides and/or alloys. For example, the adhesion layer may include cobalt, cobalt-based alloys, ruthenium, ruthenium-based alloys, iridium, iridium-based alloys, platinum, or platinum based alloys.

The intermediate layer, or adhesion layer, may be deposited as a thin layer metallic film on the barrier layer, followed by the CVD or ALD of a copper seed layer and subsequent electrofilling of the features. Preferably, the adhesion layer is also deposited using CVD or ALD to maximize deposition uniformity and conformality. The adhesion layer should provide interfacial mechanical strength, minimize diffusion of copper ions therethrough, and have a low resistivity. The inclusion of an adhesion layer between the barrier layer and the copper layer reduces the risk of delamination during subsequent CMP processes.

To date, organometallic precursors used for cobalt CVD tend to prematurely decompose upstream of the deposition chamber, in or on the walls of the deposition chamber and on the surface of the microelectronic device, which disadvantageously results in increased maintenance costs, increased time off-line, an increase in unused precursor, and an increase in defective wafers.

It is accordingly an object of the present invention to provide new cobalt precursors and formulations, as well as methods of forming thin film metallic cobalt in the manufacturing of integrated circuits and other microelectronic device structures using such precursors and formulations.

### SUMMARY OF THE INVENTION

The present invention relates generally to cobalt complexes useful as source reagents for forming cobalt-containing layers on microelectronic devices, said cobalt-containing layers having improved interfacial mechanical strength and low copper diffusibility, and to methods of making and using such cobalt complexes.

The present invention in one aspect relates to cobalt precursor compositions comprising a cobalt precursor selected from the group consisting of:

(a) aminidates, guanidates and isoureates of the formula:

R⁴ₙCo[R¹NC(R³)NR²]_{OX-n}

wherein:
R¹, R², R³ and R⁴ may be the same as or different from one another and are independently selected from the group consisting of hydrogen, halogen, C₁-C₆ alkyl, C₁-C₆ alkoxy, C₃-C₇ cycloalkyl, C₆-C₁₀ aryl, cyanide, boride, arylalkyl, aryloxy (ArO), amino, silyl, amide, and hydrocarbyl derivatives of silyl groups,
OX is the oxidation state of cobalt, and
n is an integer having a value of from 0 to OX;
(b) tetra-alkyl guanidates of the formula

R⁴ₙCo[(R¹R²)NC(NR³R⁵)N)]_{OX-n}

wherein:
R¹, R², R³, R⁴ and R⁵ may be the same as or different from one another and are independently selected from the group consisting of hydrogen, halogen, C₁-C₆ alkyl, C₁-C₆ alkoxy, C₃-C₇ cycloalkyl, C₆-C₁₀ aryl, cyanide, boride, arylalkyl, aryloxy (ArO), amino, silyl, amide, and hydrocarbyl derivatives of silyl groups,
OX is the oxidation state of cobalt, and
n is an integer having a value of from 0 to OX;
(c) carbamates and thiocarbamates of the formula:

R⁴ₙCo[(EC(R³)E]_{OX-n}

wherein:
E is either O or S,
R³ and R⁴ may be the same as or different from one another and are independently selected from the group consisting of hydrogen, halogen, C₁-C₆ alkyl, C₁-C₆ alkoxy, C₃-C₇ cycloalkyl, C₆-C₁₀ aryl, cyanide, boride, arylalkyl, aryloxy (ArO), amino, silyl, amide, and hydrocarbyl derivatives of silyl groups,
OX is the oxidation state of cobalt, and
n is an integer having a value of from 0 to OX;
(d) beta-diketonates, diketoiminates, and diketiiminates, of the formulae:

[OC(R¹)C(R³)C(R²)O]_{OX-n}Co(R⁴)ₙ

[OC(R⁵)C(R³)C(R²)N(R²)]_{OX-n}Co(R⁴)ₙ

[R⁶NC(R⁵)C(R³)C(R²)N(R¹)]_{OX-n}Co(R⁴)ₙ

[(R¹)OC(═O)C(R³)C(R²)S]_{OX-n}Co(R⁴)ₙ

wherein:
R¹, R², R³, R⁴, R⁵ and R⁶ may be the same as or different from one another and are independently selected from the group consisting of hydrogen, halogen, C₁-C₆ alkyl, C₁-C₆ alkoxy, C₃-C₇ cycloalkyl, C₆-C₁₀ aryl, cyanide, boride, arylalkyl, aryloxy (ArO), amino, silyl, amide, and hydrocarbyl derivatives of silyl groups,
OX is the oxidation state of cobalt, and
n is an integer having a value of from 0 to OX;
(e) allyls of the formulae:

R⁴ₙCo[R¹NC(R³)C(R²R⁵)]_{OX-n}

R⁴ₙCo[(R¹O)NC(R³)C(R²R⁵))]_{OX-n}

R⁴ₙCo[(R¹R⁵)NC(R³)C(R²R⁶))]_{OX-n}

R⁴Co[(ONC(R³)C(R²R¹))]

wherein:
R¹, R², R³, R⁴, R⁵ and R⁶ may be the same as or different from one another and are independently selected from the group consisting of hydrogen, halogen, C₁-C₆ alkyl, C₁-C₆ alkoxy, C₃-C₇ cycloalkyl, C₆-C₁₀ aryl, cyanide, boride, arylalkyl, aryloxy (ArO), amino, silyl, amide, and hydrocarbyl derivatives of silyl groups,
OX is the oxidation state of cobalt, and
n is an integer having a value of from 0 to OX;
(f) cyclopentadienyls of the formula:

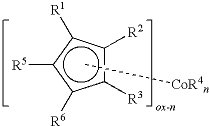

wherein:
R¹, R², R³, R⁴, R⁵ and R⁶ may be the same as or different from one another and are independently selected from the group consisting of hydrogen, halogen, C₁-C₆ alkyl, C₁-C₆ alkoxy, C₃-C₇ cycloalkyl, C₆-C₁₀ aryl, cyanide, boride, arylalkyl, aryloxy (ArO), amino, silyl, amide, and hydrocarbyl derivatives of silyl groups,
OX is the oxidation state of cobalt, and
n is an integer having a value of from 0 to OX;
(g) alkyls, alkoxides and silyls with pendent ligands, of the formulae:

R⁴ₙCo[(R¹R²)N(CH₂)ₘC(R³R⁵)]_{OX-n}

R⁴ₙCo[(R¹R²)N(CH₂)ₘSi(R³R⁵)]_{OX-n}

R⁴ₙCo[(R¹R²)N(CH₂)ₘO]_{OX-n}

wherein:
R¹, R², R³, R⁴, and R⁵ may be the same as or different from one another and are independently selected from the group consisting of hydrogen, halogen, C₁-C₆ alkyl, C₁-C₆ alkoxy, C₃-C₇ cycloalkyl, C₆-C₁₀ aryl, cyanide, boride, arylalkyl, aryloxy (ArO), amino, silyl, amide, and hydrocarbyl derivatives of silyl groups,
OX is the oxidation state of cobalt,
m is an integer having a value of from 1 to 4; and
n is an integer having a value of from 0 to OX;
(h) silyamides(cyclic) and chelate amides, of the formulae:

R⁴ₙCo[N[(R¹R²)Si(CH₂)ₘSi(R³R⁵)]]_{OX-n}

R⁴ₙCo[N(R¹R²)]_{OX-n}

R⁴ₙCo[N[(R¹R²C)(CH₂)ₘ(R³R⁵C)]]_{OX-n}

R⁴ₙCo[(N(R¹R²)(CH₂)ₘ(NR³R⁵)]]_{(OX-n)/2}

wherein:
R¹, R², R³, R⁴, and R⁵ may be the same as or different from one another and are independently selected from the group consisting of hydrogen, halogen, C₁-C₆ alkyl, C₁-C₆ alkoxy, C₃-C₇ cycloalkyl, C₆-C₁₀ aryl, cyanide, boride, arylalkyl, aryloxy (ArO), amino, silyl, amide, and hydrocarbyl derivatives of silyl groups,
OX is the oxidation state of cobalt,
m is an integer having a value of from 1 to 4; and
n is an integer having a value of from 0 to OX;
(i) carbodiimide guanidinates of the formulae:

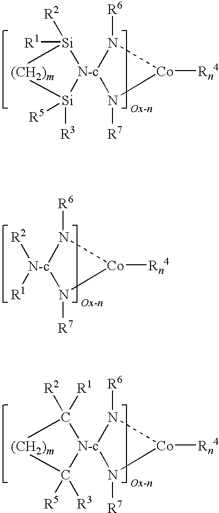

wherein:
R¹, R², R³, R⁴, R⁵, R⁶ and R⁷ may be the same as or different from one another and are independently selected from the group consisting of hydrogen, halogen, C₁-C₆ alkyl, C₁-C₆ alkoxy, C₃-C₇ cycloalkyl, C₆-C₁₀ aryl, cyanide, boride, arylalkyl, aryloxy (ArO), amino, silyl, amide, and hydrocarbyl derivatives of silyl groups,
OX is the oxidation state of cobalt,
m is an integer having a value of from 1 to 4; and
n is an integer having a value of from 0 to OX;
(j) cobalt borohydride compounds of the formula:

CoBₓH_{y}Lₙ

wherein x and y are integers related to one another by Wade's rule, L is a Lewis base including, but not limited to, tertiary phosphines, amines, alkynes, imidazole and thiolate, n is an integer having a value of from 0 to 6, wherein when n>1, each L may be the same as or different from one another; and
(k) cobalt borohydride cyclopentadienyl compounds of the formula:

CoBₓH_{y}LₙCp

wherein x and y are integers related to one another by Wade's rule; L is a Lewis base, e.g., a Lewis base selected from the group consisting of tertiary phosphines, amines, alkynes, imidazole, isonitriles, dienes, and thiol; n is an integer having a value of from 0 to 6; and Cp is cyclopentadienyl of the formula:

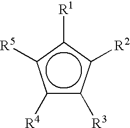

wherein R¹, R², R³, R⁴ and R⁵ may be the same as or different from one another and are independently selected from the group consisting of hydrogen, halogen, C₁-C₆ alkyl, C₁-C₆ alkoxy, C₃-C₇ cycloalkyl, C₆-C₁₀ aryl, cyanide, boride, arylalkyl, aryloxy (ArO), amino, silyl, amide, and hydrocarbyl derivatives of silyl groups, wherein when n>1, the Lewis bases may be the same as or different from one another;
(l) cyclopentadienyl compounds of the formula:

CpCo(CO)₂

wherein:
Cp is cyclopentadienyl of the formula:

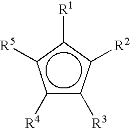

wherein R¹, R², R³, R⁴ and R⁵ may be the same as or different from one another and are independently selected from the group consisting of hydrogen, halogen, C₁-C₆ alkyl, C₁-C₆ alkoxy, C₃-C₇ cycloalkyl, C₆-C₁₀ aryl, cyanide, boride, arylalkyl, aryloxy (ArO), amino, silyl, amide, and hydrocarbyl derivatives of silyl groups; and
(m) cyclopentadienyl compounds of the formula:

CpCo(CO)₃L

wherein:
Cp is cyclopentadienyl of the formula:

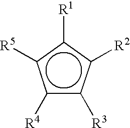

wherein:
R¹, R², R³, R⁴ and R⁵ may be the same as or different from one another and are independently selected from the group consisting of hydrogen, halogen, C₁-C₆ alkyl, C₁-C₆ alkoxy, C₃-C₇ cycloalkyl, C₆-C₁₀ aryl, cyanide, boride, arylalkyl, aryloxy (ArO), amino, silyl, amide, and hydrocarbyl derivatives of silyl groups, and
L=NO or R^{a}—C≡C—R^{b}, where R^{a} and R^{b} can be the same as or different from one another and each is independently selected from among hydrogen, halogen, C₁-C₆ alkyl, C₁-C₆ alkoxy, C₃-C₇ cycloalkyl, C₆-C₁₀ aryl, cyanide, boride, arylalkyl, aryloxy (ArO), amino, silyl, amide, and hydrocarbyl derivatives of silyl groups.

The present invention in another aspect relates to cobalt precursor compositions comprising a cobalt precursor selected from the group consisting of:

(a)

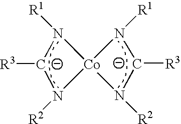

wherein R₁, R₂, and R₃ may be the same as or different from one another and are independently selected from the group consisting of hydrogen, halogen, C₁-C₆ alkyl, C₁-C₆ alkoxy, C₃-C₇ cycloalkyl, cyanide, boride, aryl, aryloxy (ArO), amino and hydrocarbyl derivatives of silyl groups, with the proviso that when each of R¹ and R² is independently either isopropyl or t-butyl, both R³ are not methyl;
(b)

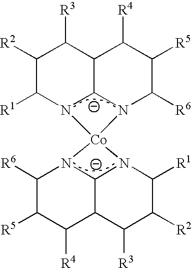

wherein R₁ to R₆ can be the same as or different from one another and are independently selected from the group consisting of hydrogen and C₁-C₄ alkyls;
(c)

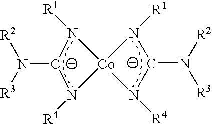

where each of R₁ to R₆ is the same as or different from one another and is independently selected from the group consisting of hydrogen, C₁-C₄ alkyl, C₁-C₆ alkoxy, and hydrocarbyl derivatives of silyl groups;
(d)

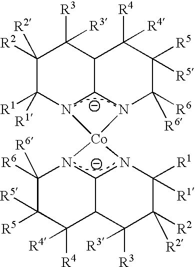

where R₁ to R₆ are the same as or different from one another and are independently selected from the group consisting of hydrogen, C₁-C₄ alkyl, C₁-C₆ alkoxy, and hydrocarbyl derivatives of silyl groups;
(e) CoBₓH_{y}Lₙ, wherein x and y are integers related to one another by Wade's rule, L is a Lewis base including, but not limited to, tertiary phosphines, amines, alkynes, imidazole and thiolate,

n is an integer from 0 to 6, wherein when n>1, L may be the same as or different from one another;

(f) CoBₓH_{y}LₙCp: wherein x and y are integers related to one another by Wade's rule; L is a Lewis base, e.g., a Lewis base selected from the group consisting of tertiary phosphines, amines, alkynes, imidazole, isonitriles, dienes, and thiol; n is an integer from 0 to 6; and Cp is cyclopentadienyl of the formula:

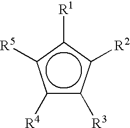

wherein R¹, R², R³, R⁴ and R⁵ may be the same as or different from one another and are independently selected from the group consisting of hydrogen, C₁-C₆ alkyl, and amino wherein when n>1, the Lewis bases may be the same as or different from one another;
(g)

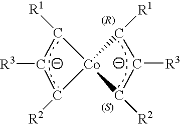

where R₁, R₂, and R₃ may be the same as or different from one another and are independently selected from the group consisting of hydrogen, halogen, C₁-C₆ alkyl, C₁-C₆ alkoxy, C₃-C₇ cycloalkyl, cyanide, boride, aryl, aryloxy (ArO), hydrocarbyl derivatives of silyl groups, and NR⁴R⁵, wherein R⁴ and R⁵ may be the same as or different from one another and are independently selected from the group consisting of H, C₁-C₆ alkyl, C₃-C₇ cycloalkyl, aryl, amino and hydrocarbyl derivatives of silyl groups, with the proviso that when each of R¹ and R² is trimethylsilyl, both R³ are not hydrogen;

CpCo(CO)₂ (h)

wherein Cp is as defined above;

Cp₂Co (i)

wherein Cp is as defined above; and

Co(CO)₃L (j)

wherein L=NO or R^{a}—C≡C—R^{b}, where R^{a} and R^{b} can be the same as or different from one another and each is independently selected from among C₁-C₆ alkyl, C₁-C₆ alkoxy, C₃-C₇ cycloalkyl, cyanide, boride, aryl, aryloxy (ArO), amino and hydrocarbyl derivatives of silyl groups.

In another aspect, the present invention relates to a cobalt precursor formulation, comprising: (i) a cobalt precursor compound comprising a cobalt species as described above, and (ii) a solvent composition or diluent for the precursor compound.

A further aspect of the invention relates to a method of depositing cobalt on a microelectronic device substrate, comprising: (i) volatilizing a cobalt precursor comprising a cobalt species; and (ii) contacting the volatilized cobalt precursor with the microelectronic device substrate under elevated temperature vapor decomposition conditions to deposit cobalt on said substrate.

Another aspect of the invention relates to a vapor of a cobalt precursor of a type as described above.

A still further aspect of the invention relates to a method of manufacturing a microelectronic device, comprising delivery of a cobalt precursor species described above, to a microelectronic device manufacturing tool.

Another aspect of the invention relates to a method of manufacturing a microelectronic device, comprising delivery of a cobalt precursor composition of the invention, to a microelectronic device manufacturing tool.

A further aspect of the invention relates to a precursor source package comprising a vessel containing a cobalt precursor composition of the invention, and a dispensing assembly coupled with the vessel and adapted for dispensing the cobalt precursor composition from the vessel.

Other aspects, features and embodiments of the invention will be more fully apparent from the ensuing disclosure and appended claims.

### BRIEF DESCRIPTION OF THE DRAWINGS

FIG. 1 is a schematic representation of a process system according to one embodiment of the invention, in which a cobalt precursor composition of the invention is supplied to a semiconductor manufacturing tool, and the effluent from the tool is subjected to abatement/reclamation treatment.

FIG. 2 is a schematic representation of a microelectronic device structure comprising a cobalt barrier layer deposited on a dielectric layer on a substrate, wherein the cobalt barrier layer has a copper layer deposited thereon.

### DETAILED DESCRIPTION OF THE INVENTION, AND PREFERRED EMBODIMENTS THEREOF

The present invention relates generally to novel cobalt precursor compositions, including cobalt amidinates, cobalt guanidinates, cobalt hydrides and cobalt allyl complexes, and to the CVD and ALD formation of thin film metallic cobalt on microelectronic device structures using said precursors.

As defined herein, “microelectronic device” corresponds to semiconductor substrates, flat panel displays, and microelectromechanical systems (MEMS), manufactured for use in microelectronic, integrated circuit, or computer chip applications. It is to be understood that the term “microelectronic device” is not meant to be limiting in any way and includes any substrate that will eventually become a microelectronic device or microelectronic assembly.

As defined herein, “adhesion layers” corresponds to any layer having direct interfacial contact with a copper-containing layer thereby improving the adhesion of the copper-containing layer with other layers, including barrier layers and insulating layers, of the microelectronic device.

As used herein, the reference to an organo substituent, e.g., alkyl, alkoxy, cycloalkyl, etc., specifying same by a carbon number range, e.g., C₁-C₆ alkyl, shall in each instance be construed and interpreted as specifying each of the component substituents in such range, e.g., C₁-C₆ alkyl=methyl, ethyl, propyl, butyl, pentyl and hexyl, and it will be understood that the invention contemplates more specific substituent subgroups within such carbon number ranges, such as may be specified by selection of only certain of the substituents of the broader range, or as subject to provisos excluding one or more members of the compounds within broader carbon number ranges, in specific embodiments of the invention.

It is to be noted that the utility of these precursor materials, and the cobalt films formed thereby, are not limited to copper adhesion layers, but rather extend to and include other functional applications, such as, for example in electrodes, conductors, resistive layers, magnetically active layers, reflectors, and the like.

The invention in one aspect thereof relates to cobalt precursor compositions comprising a cobalt precursor selected from the group consisting of:

(a) amimidates, guanidates and isoureates of the formula:

R⁴ₙCo[R¹NC(R³)NR²]_{OX-n}

wherein:
R¹, R², R³ and R⁴ may be the same as or different from one another and are independently selected from the group consisting of hydrogen, halogen, C₁-C₆ alkyl, C₁-C₆ alkoxy, C₃-C₇ cycloalkyl, C₆-C₁₀ aryl, cyanide, boride, arylalkyl, aryloxy (ArO), amino, silyl, amide, and hydrocarbyl derivatives of silyl groups,
OX is the oxidation state of cobalt, and
n is an integer having a value of from 0 to OX;
(b) tetra-alkyl guanidates of the formula

R⁴ₙCo[(R¹R²)NC(NR³R⁵)N)]_{OX-n}

wherein:
R¹, R², R³, R⁴ and R⁵ may be the same as or different from one another and are independently selected from the group consisting of hydrogen, halogen, C₁-C₆ alkyl, C₁-C₆ alkoxy, C₃-C₇ cycloalkyl, C₆-C₁₀ aryl, cyanide, boride, arylalkyl, aryloxy (ArO), amino, silyl, amide, and hydrocarbyl derivatives of silyl groups,
OX is the oxidation state of cobalt, and
n is an integer having a value of from 0 to OX;
(c) carbamates and thiocarbamates of the formula:

R⁴ₙCo[(EC(R³)E]_{OX-n}

wherein:
E is either O or S,
R³ and R⁴ may be the same as or different from one another and are independently selected from the group consisting of hydrogen, halogen, C₁-C₆ alkyl, C₁-C₆ alkoxy, C₃-C₇ cycloalkyl, C₆-C₁₀ aryl, cyanide, boride, arylalkyl, aryloxy (ArO), amino, silyl, amide, and hydrocarbyl derivatives of silyl groups,
OX is the oxidation state of cobalt, and
n is an integer having a value of from 0 to OX;
(d) beta-diketonates, diketoiminates, and diketiiminates, of the formulae:

[OC(R¹)C(R³)C(R²)O]_{OX-n}Co(R⁴)ₙ

[OC(R⁵)C(R³)C(R²)N(R¹)]_{OX-n}Co(R⁴)ₙ

[R⁶NC(R⁵)C(R³)C(R²)N(R¹)]_{OX-n}Co(R⁴)ₙ

[(R¹)OC(═O)C(R³)C(R²)S]_{OC-n}Co(R⁴)ₙ

wherein:
R¹, R², R³, R⁴, R⁵ and R⁶ may be the same as or different from one another and are independently selected from the group consisting of hydrogen, halogen, C₁-C₆ alkyl, C₁-C₆ alkoxy, C₃-C₇ cycloalkyl, C₆-C₁₀ aryl, cyanide, boride, arylalkyl, aryloxy (ArO), amino, silyl, amide, and hydrocarbyl derivatives of silyl groups,
OX is the oxidation state of cobalt, and
n is an integer having a value of from 0 to OX;
(e) allyls of the formulae:

R⁴ₙCo[R¹NC(R³)C(R²R⁵)]_{OX-n}

R⁴ₙCo[(R¹O)NC(R³)C(R²R⁵))]_{OX-n}

R⁴ₙCo[(R¹R⁵)NC(R³)C(R²R⁶))]_{OX-n}

R⁴Co[(ONC(R³)C(R²R¹))]

wherein:
R¹, R², R³, R⁴, R⁵ and R⁶ may be the same as or different from one another and are independently selected from the group consisting of hydrogen, halogen, C₁-C₆ alkyl, C₁-C₆ alkoxy, C₃-C₇ cycloalkyl, C₆-C₁₀ aryl, cyanide, boride, arylalkyl, aryloxy (ArO), amino, silyl, amide, and hydrocarbyl derivatives of silyl groups,
OX is the oxidation state of cobalt, and
n is an integer having a value of from 0 to OX;
(f) cyclopentadienyls of the formula:

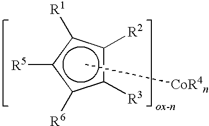

wherein:
R¹, R², R³, R⁴, R⁵ and R⁶ may be the same as or different from one another and are independently selected from the group consisting of hydrogen, halogen, C₁-C₆ alkyl, C₁-C₆ alkoxy, C₃-C₇ cycloalkyl, C₆-C₁₀ aryl, cyanide, boride, arylalkyl, aryloxy (ArO), amino, silyl, amide, and hydrocarbyl derivatives of silyl groups,
OX is the oxidation state of cobalt, and
n is an integer having a value of from 0 to OX;
(g) alkyls, alkoxides and silyls with pendent ligands, of the formulae:

R⁴ₙCo[(R¹R²)N(CH₂)ₘC(R³R⁵)]_{OX-n}

R⁴ₙCo[(R¹R²)N(CH₂)ₘSi(R³R⁵)]_{OX-n}

R⁴ₙCo[(R¹R²)N(CH₂)ₘO]_{OX-n}

wherein:
R¹, R², R³, R⁴, and R⁵ may be the same as or different from one another and are independently selected from the group consisting of hydrogen, halogen, C₁-C₆ alkyl, C₁-C₆ alkoxy, C₃-C₇ cycloalkyl, C₆-C₁₀ aryl, cyanide, boride, arylalkyl, aryloxy (ArO), amino, silyl, amide, and hydrocarbyl derivatives of silyl groups,
OX is the oxidation state of cobalt,
m is an integer having a value of from 1 to 4; and
n is an integer having a value of from 0 to OX;
(h) silyamides(cyclic) and chelate amides, of the formulae:

R⁴ₙCo[N[(R¹R²)Si(CH₂)ₘSi(R³R⁵)]]_{OX-n}

R⁴ₙCo[N(R¹R²)]_{OX-n}

R⁴ₙCo[N[(R¹R²C)(CH₂)ₘ(R³R⁵C)]]_{OX-n}

R⁴ₙCo[(N(R¹R²)(CH₂)ₘ(NR³R⁵)]]_{(OX-n)/2}

wherein:
R¹, R², R³, R⁴, and R⁵ may be the same as or different from one another and are independently selected from the group consisting of hydrogen, halogen, C₁-C₆ alkyl, C₁-C₆ alkoxy, C₃-C₇ cycloalkyl, C₆-C₁₀ aryl, cyanide, boride, arylalkyl, aryloxy (ArO), amino, silyl, amide, and hydrocarbyl derivatives of silyl groups,
OX is the oxidation state of cobalt,
m is an integer having a value of from 1 to 4; and
n is an integer having a value of from 0 to OX;
(i) carbodiimide guanidinates of the formulae:

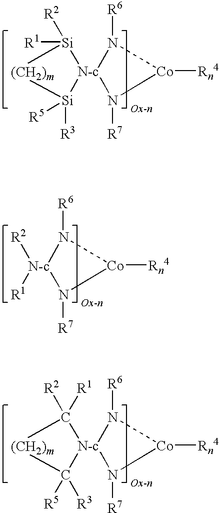

wherein:
R¹, R², R³, R⁴, R⁵, R⁶ and R⁷ may be the same as or different from one another and are independently selected from the group consisting of hydrogen, halogen, C₁-C₆ alkyl, C₁-C₆ alkoxy, C₃-C₇ cycloalkyl, C₆-C₁₀ aryl, cyanide, boride, arylalkyl, aryloxy (ArO), amino, silyl, amide, and hydrocarbyl derivatives of silyl groups,
OX is the oxidation state of cobalt,
m is an integer having a value of from 1 to 4; and
n is an integer having a value of from 0 to OX;
(j) cobalt borohydride compounds of the formula:

COBₓH_{y}Lₙ

wherein x and y are integers related to one another by Wade's rule, L is a Lewis base including, but not limited to, tertiary phosphines, amines, alkynes, imidazole and thiolate, n is an integer having a value of from 0 to 6, wherein when n>1, each L may be the same as or different from one another; and
(k) cobalt borohydride cyclopentadienyl compounds of the formula:

CoBₓH_{y}LₙCp

wherein x and y are integers related to one another by Wade's rule; L is a Lewis base, e.g., a Lewis base selected from the group consisting of tertiary phosphines, amines, alkynes, imidazole, isonitriles, dienes, and thiol; n is an integer having a value of from 0 to 6; and Cp is cyclopentadienyl of the formula:

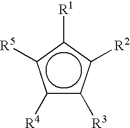

wherein R¹, R², R³, R⁴ and R⁵ may be the same as or different from one another and are independently selected from the group consisting of hydrogen, halogen, C₁-C₆ alkyl, C₁-C₆ alkoxy, C₃-C₇ cycloalkyl, C₆-C₁₀ aryl, cyanide, boride, arylalkyl, aryloxy (ArO), amino, silyl, amide, and hydrocarbyl derivatives of silyl groups, wherein when n>1, the Lewis bases may be the same as or different from one another;
(l) cyclopentadienyl compounds of the formula:

CpCo(CO)₂

wherein:
Cp is cyclopentadienyl of the formula:

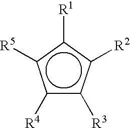

wherein R¹, R², R³, R⁴ and R⁵ may be the same as or different from one another and are independently selected from the group consisting of hydrogen, halogen, C₁-C₆ alkyl, C₁-C₆ alkoxy, C₃-C₇ cycloalkyl, C₆-C₁₀ aryl, cyanide, boride, arylalkyl, aryloxy (ArO), amino, silyl, amide, and hydrocarbyl derivatives of silyl groups; and
(m) cyclopentadienyl compounds of the formula:

CpCo(CO)₃L

wherein:
Cp is cyclopentadienyl of the formula:

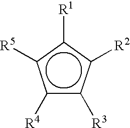

wherein:
R¹, R², R³, R⁴ and R⁵ may be the same as or different from one another and are independently selected from the group consisting of hydrogen, halogen, C₁-C₆ alkyl, C₁-C₆ alkoxy, C₃-C₇ cycloalkyl, C₆-C₁₀ aryl, cyanide, boride, arylalkyl, aryloxy (ArO), amino, silyl, amide, and hydrocarbyl derivatives of silyl groups, and
L=NO or R^{a}—C≡C—R^{b}, where R^{a} and R^{b} can be the same as or different from one another and each is independently selected from among hydrogen, halogen, C₁-C₆ alkyl, C₁-C₆ alkoxy, C₃-C₇ cycloalkyl, C₆-C₁₀ aryl, cyanide, boride, arylalkyl, aryloxy (ArO), amino, silyl, amide, and hydrocarbyl derivatives of silyl groups.

The above-discussed cobalt precursors (a)-(i) include those of the following structural formulae:

(a) aminidates, guanidates and isoureates of the structural formula:

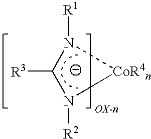

(b) tetra-alkyl guanidates of the structural formula

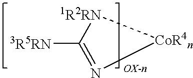

(c) carbamates and thiocarbamates of the structural formula:

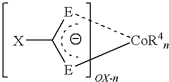

wherein x=R³ as defined in (c) hereinabove
(d) beta-diketonates, diketoiminates, and diketiiminates, of the structural formulae:

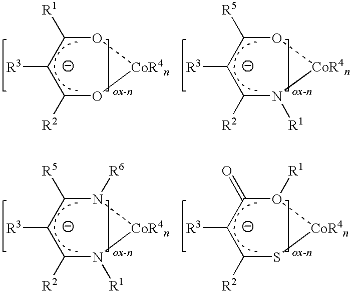

(e) allyls of the structural formulae:

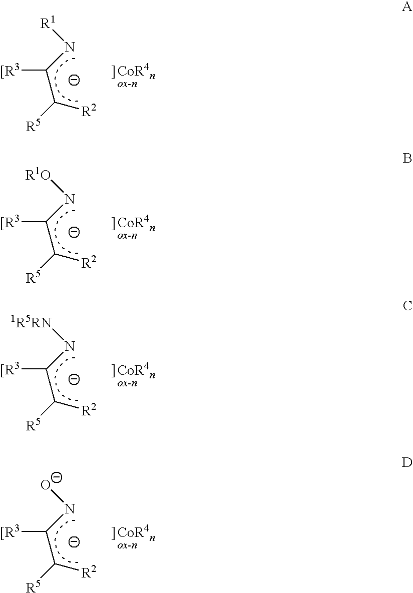

(f) cyclopentadienyls of the structural formula:

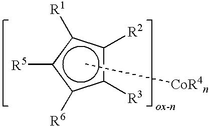

(g) alkyls, alkoxides and silyls with pendent ligands, of the structural formulae:

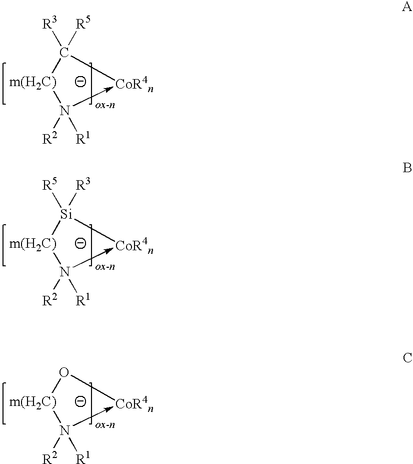

(h) silyamides(cyclic) and chelate amides, of the structural formulae:

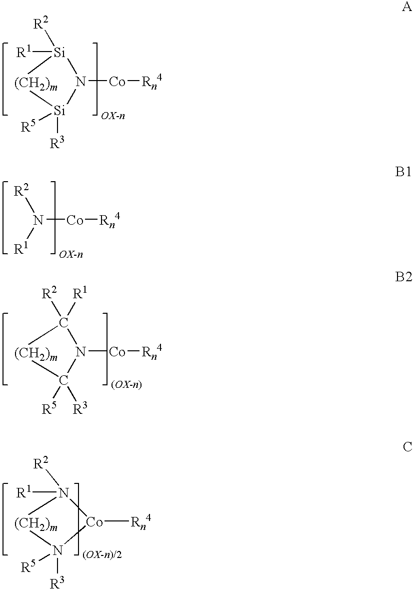

(i) carbodiimide guanidinates of the structural formulae:

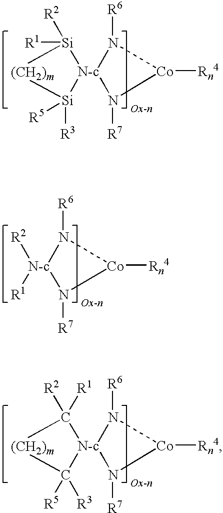

in which the carbodiimide guanidinates can be synthesized by carbodiimide insertion reaction, as follows:

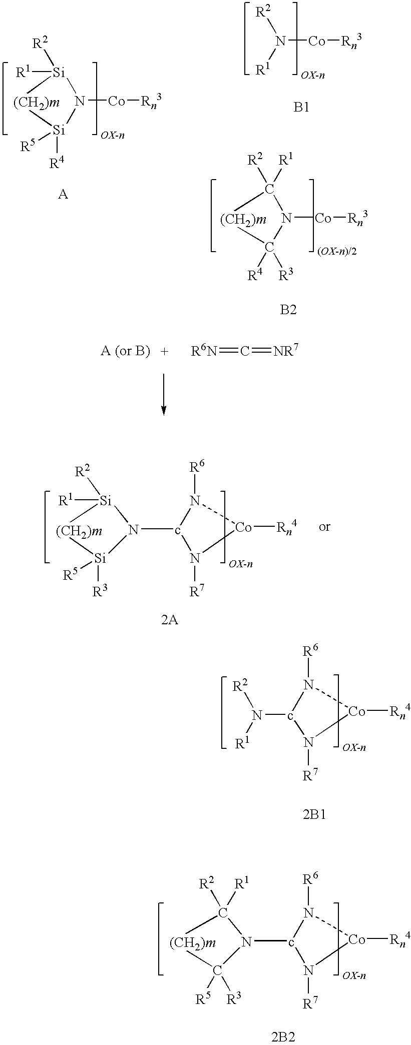

Amidinates are bulky monoanionic ligands which have the basic chemical structure:

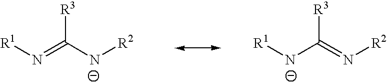

where R₁, R₂, and R₃ may be the same as or different from one another and are selected from hydrogen, halogen, C₁-C₆ alkyl, C₁-C₆ alkoxy, C₃-C₇ cycloalkyl, cyanide, boride, aryl, aryloxy (ArO), amino and hydrocarbyl derivatives of silyl groups; and

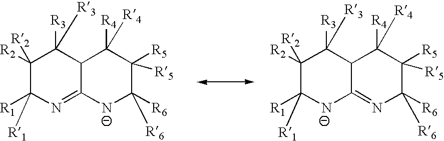

wherein each of R₁ to R₆ and R′₁ to R′₆ can be the same as or different from one another and each is independently selected from among hydrogen and C₁-C₄ alkyls.

Guanidinates have the basic chemical structures shown below:

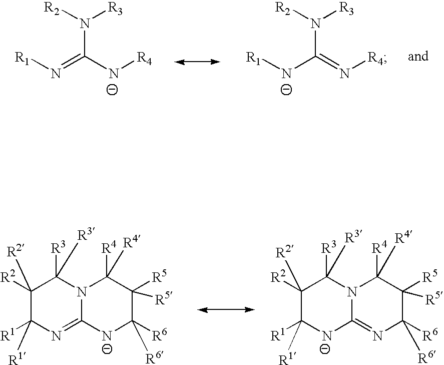

wherein each of R₁ to R₆ and R′₁ to R′₆ can be the same as or different from one another and each is independently selected from among hydrogen, C₁-C₄ alkyl, C₁-C₆ alkoxy, and hydrocarbyl derivatives of silyl groups.

In one aspect, the invention relates to novel cobalt (II) amidinate compounds of formula (1):

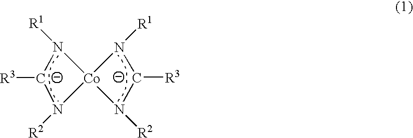

wherein R₁, R₂, and R₃ may be the same as or different from one another and are selected from hydrogen, halogen, C₁-C₆ alkyl, C₁-C₆ alkoxy, C₃-C₇ cycloalkyl, cyanide, boride, aryl, aryloxy (ArO), amino and hydrocarbyl derivatives of silyl groups, with the proviso that when each of R¹ and R² is independently either isopropyl or t-butyl, both R³ are not methyl.

In another aspect, the invention relates to novel cobalt (II) amidinate compounds of formula (2):

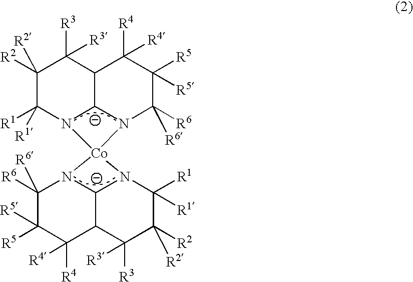

wherein each of R₁ to R₆ and R′₁ to R′₆ can be the same as or different from one another and each is independently selected from among hydrogen and C₁-C₄ alkyls.

In yet another aspect, the invention relates to novel cobalt (II) guanidinate compounds of formulas (3) and (4):

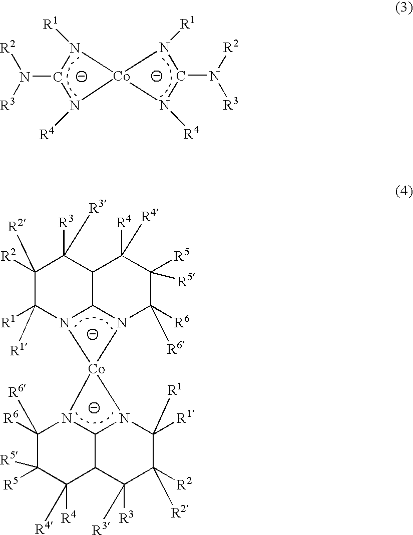

wherein each of R₁ to R₆ and R′₁ to R′₆ can be the same as or different from one another and each is independently selected from among hydrogen, C₁-C₄ alkyl, C₁-C₆ alkoxy, and hydrocarbyl derivatives of silyl groups.

The compounds of formulas (1)-(4) are usefully employed for forming cobalt thin films by CVD or ALD processes, utilizing process conditions, including appertaining temperatures, pressures, concentrations, flow rates and CVD or ALD techniques, as readily determinable within the skill of the art for a given application.

Preferably, the deposited cobalt thin films are metallic thin films comprising at least 95 wt. % cobalt, preferably at least 98 wt. % cobalt, even more preferably at least 99 wt. % cobalt, thereby minimizing the resistivity associated with the adhesion layer.

Compounds of formulas (1)-(4) are readily synthesized according to the following reaction scheme (A):

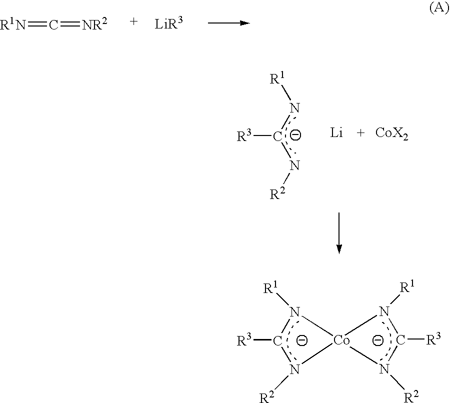

In yet another aspect, the invention relates to novel cobalt hydride compounds. Cobalt hydrides are notoriously unstable species and as such, the cobalt hydride compounds of the invention include bulky, electron deficient groups to stabilize the compounds. Cobalt hydrides contemplated herein have the general formulas CoBₓH_{y}Lₙ or CoBₓH_{y}LₙCp, wherein x and y are integers related to one another by Wade's rule, L is a Lewis base including, but not limited to, tertiary phosphines, amines, alkynes, imidazole, isonitriles, dienes, and thiol, n is an integer from 0 to 6, and Cp is a cyclopentadienyl having the formula:

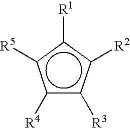

where R¹, R², R³, R⁴ and R⁵ may be the same as or different from one another and are selected from the group consisting of hydrogen, C₁-C₆ alkyl, and amino groups. Importantly, when n>1, the Lewis bases may be the same as or different from one another.

Cobalt hydrides contemplated herein include, but are not limited to, formulas (5)-(8):

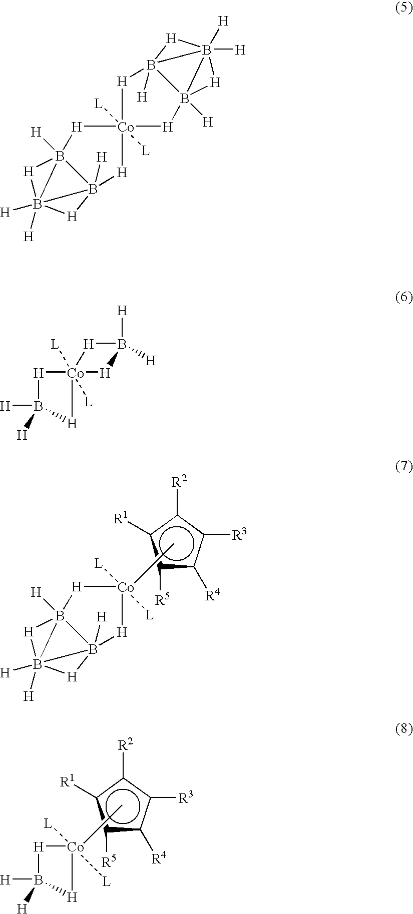

wherein R¹, R², R³, R⁴ and R⁵ may be the same as or different from one another and are selected from the group consisting of hydrogen and C₁-C₆ alkyl. It is noted that formulas (5)-(8) include a depiction of two Lewis bases per formula, however, the choice of two Lewis bases per formula is merely illustrative. As introduced hereinabove, the formulas may include anywhere from zero to six Lewis base constituents, as readily determined by one skilled in the art. Moreover, when n>1, the Lewis bases may be the same as or different from one another.

Advantageously, cobalt thin films deposited using the cobalt hydrides of the present invention will contain less carbon and nitrogen contaminants because of the low carbon and nitrogen content of the cobalt hydride precursors. As such, the deposited cobalt thin films will have a lower resistivity than corresponding films with higher levels of contaminants, e.g., carbon, nitrogen, etc.

The compounds of formulas (5)-(8) are usefully employed for forming cobalt thin films by CVD or ALD processes, utilizing process conditions, including appertaining temperatures, pressures, concentrations, flow rates and CVD or ALD techniques, as readily determinable within the skill of the art for a given application. Preferably, the deposited cobalt thin films are metallic thin films comprising at least 95 wt. % cobalt, preferably at least 98 wt. % cobalt, even more preferably at least 99 wt. % cobalt, thereby minimizing the resistivity associated with the adhesion layer. A certain amount of boron (0.1-2%) may be intentionally incorporated to decrease grain boundary diffusion. In an alternative embodiment, instead of metallic cobalt thin films, cobalt borides may be deposited using the cobalt hydride precursors disclosed herein according to the deposition methodologies of the present invention.

Compounds of formulas (5)-(8) are readily synthesized according to the following reaction schemes (B)-(E), respectively:

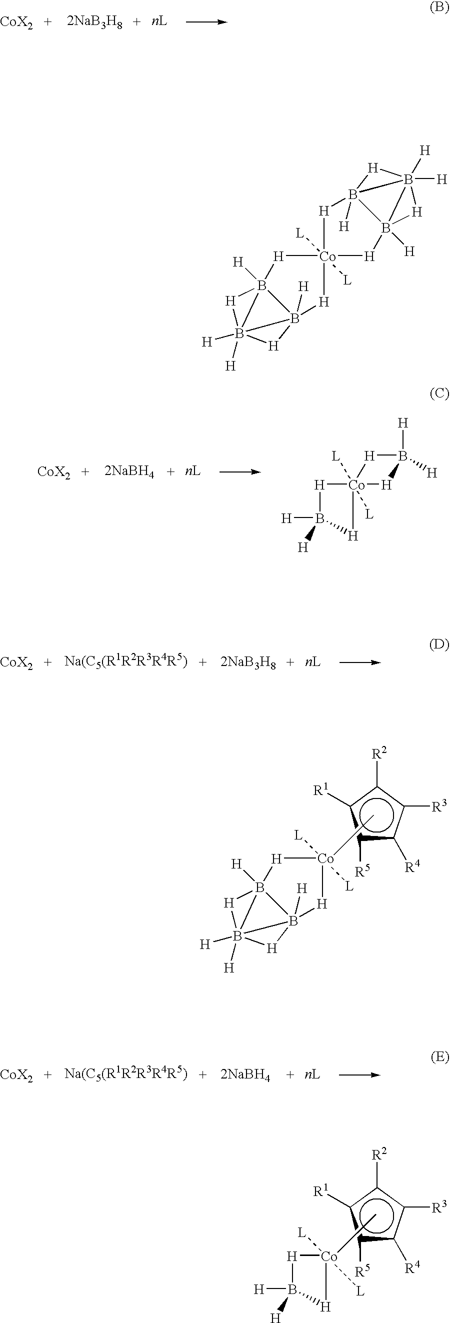

In yet another aspect, the invention relates to novel cobalt allyl complexes of formula (9):

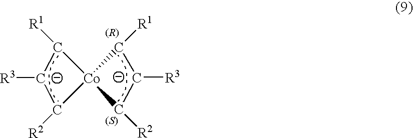

where R₁, R₂, and R₃ may be the same as or different from one another and are selected from hydrogen, halogen, C₁-C₆ alkyl, C₁-C₆ alkoxy, C₃-C₇ cycloalkyl, cyanide, boride, aryl, aryloxy (ArO), hydrocarbyl derivatives of silyl groups, and NR⁴R⁵, where R⁴ and R⁵ may be the same as or different from one another and is independently selected from the group consisting of H, C₁-C₆ alkyl, C₃-C₇ cycloalkyl, aryl, and hydrocarbyl derivatives of silyl groups, with the proviso that when each of R¹ and R² is trimethylsilyl, both R³ are not hydrogen.

To date, cobalt allyl complexes have not been fully investigated for use as CVD/ALD precursors because of concerns relating to potential thermal instability. However, due to increasing interest in lower temperature deposition to address conformity and step-coverage issues associated with higher temperature deposition, thermally unstable compounds such as cobalt allyl complexes may considered viable cobalt thin film precursors.

The compounds of formula (9) are usefully employed for forming cobalt thin films by CVD or ALD processes, utilizing process conditions, including appertaining temperatures, pressures, concentrations, flow rates and CVD or ALD techniques, as readily determinable within the skill of the art for a given application. Preferably, the deposited cobalt thin films are metallic thin films comprising at least 95 wt. % cobalt, preferably at least 98 wt. % cobalt, even more preferably at least 99 wt. % cobalt, thereby minimizing the resistivity associated with the adhesion layer.

Compounds of formula (9) are readily synthesized according to the following reaction scheme (F):

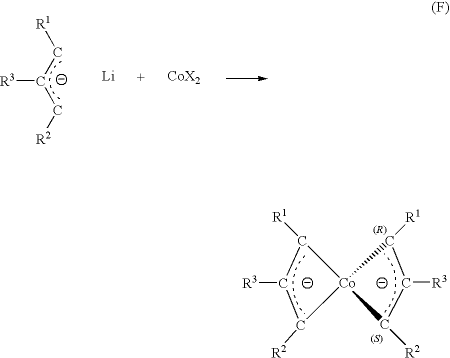

A further aspect of the invention relates to cobalt compounds of formulae (10)-(12):

CpCo(CO)₂ (10)

wherein Cp is as defined above;

Cp₂Co (11)

wherein Cp is as defined above; and

Co(CO)₃L (12)

wherein L=NO or R^{a}—C≡C—R^{b}, and R^{a} and R^{b} can be the same as or different from one another and each is independently selected from among C₁-C₆ alkyl, C₁-C₆ alkoxy, C₃-C₇ cycloalkyl, cyanide, boride, aryl, aryloxy (ArO), amino and hydrocarbyl derivatives of silyl groups such as trimethylsilyl.

The compounds of formulae (10)-(12) are readily synthesized in a manner analogous to the synthetic methods described hereinabove, or otherwise within the skill of the art, given their formulae herein. Such compounds are usefully employed for forming cobalt thin films by CVD or ALD processes, utilizing process conditions, including appertaining temperatures, pressures, concentrations, flow rates and CVD or ALD techniques, as readily determinable within the skill of the art for a given application.

In CVD or ALD usage, the cobalt (II) precursors of the invention are volatilized to form a precursor vapor that is then contacted with a substrate under deposition conditions to deposit cobalt on the substrate. The cobalt (II) precursors are volatile and thermally stable at the deposition temperatures disclosed herein, and are usefully employed as cobalt CVD or ALD precursors.

For example, CVD and ALD processes contemplated herein include, but are not limited to: thermal CVD whereby the precursor and co-reactants are fed simultaneously into the deposition chamber; thermal CVD whereby the precursor and co-reactants are separated in a pulse train, optionally with a pulse purge between doses of precursor and co-reactants; and ALD, wherein the precursor and co-reactants are alternately dosed in a self-limiting deposition mode. Suitable co-reactants include hydrogen gas, hydrogen transfer agents such as tetralin, a hydrogen gas/inert gas mixture, alkenes, alkynes, boranes, amides, imines, silanes, borohydrides such as diborane, alcohols, carbon monoxide, reducing gases, amines and ammonia. Any of these co-reactants may also be activated by a plasma or hot wire or other means or methods known in the art. Co-reactants may be advantageous in reducing carbon contamination in the resultant deposited cobalt film. Inert gases contemplated herein include, but are not limited to, helium, argon, krypton, and nitrogen.

In a preferred embodiment, the co-reactant includes nitrogen in the initial stages of the deposition process (e.g., during formation of the initial monolayer(s)) to ensure a strong bond is formed between the cobalt-containing film and the barrier layer, e.g., TaN, followed by subsequent cycles which employ reducing gases to minimize the presence of contaminants in the remainder of the deposited thin film metallic cobalt.

The compositions of the present invention may be delivered to a CVD or ALD reactor in a variety of ways. For example, a liquid delivery system may be utilized. Alternatively, a combined liquid delivery and flash vaporization process unit may be employed, such as the LDS300 liquid delivery and vaporizer unit (commercially available from Advanced Technology Materials, Inc., Danbury, Conn., USA), to enable low volatility materials to be volumetrically delivered, leading to reproducible transport and deposition without thermal decomposition of the precursor. Both of these considerations of reproducible transport and deposition without thermal decomposition are essential for providing a commercially acceptable cobalt CVD or ALD process.

In liquid delivery formulations, cobalt precursors that are liquids may be used in neat liquid form, or liquid or solid cobalt precursors may be employed in solvent or diluent formulations containing same. Thus, cobalt precursor formulations of the invention may include solvent component(s) of suitable character as may be desirable and advantageous in a given end use application to form cobalt on a microelectronic device. Suitable solvents may for example include alkane solvents, e.g., hexane, heptane, octane, pentane, or aryl solvents such as benzene or toluene, amines and amides. The utility of specific solvent compositions for particular cobalt precursors may be readily empirically determined, to select an appropriate single component or multiple component solvent medium for the liquid delivery vaporization and transport of the specific cobalt precursor employed.

In another embodiment of the invention, a solid delivery system may be utilized, for example, using the ProE-Vap solid delivery and vaporizer unit (commercially available from Advanced Technology Materials, Inc., Danbury, Conn., USA).

A wide variety of CVD or ALD process conditions may be utilized with the precursor compositions of the present invention. Generalized process conditions may include substrate temperature ranges of 100-450° C., preferably 200-400° C.; pressure ranges of 0.05-50 Torr; and optionally carrier gas flows of helium, hydrogen, nitrogen, or argon at 25-750 sccm at a temperature approximately the same as the vaporizer of 50 to 190° C.

The deposited cobalt-containing adhesion layers may be annealed prior to subsequent copper seed-layer deposition. Annealing conditions include temperature in a range from about 200° C. to about 500° C. in a reducing environment.

By way of example, the cobalt (II) precursor compositions of the present invention may be used during the formation of adhesion layers in semiconductor integrated circuitry, thin-film circuitry, thin-film packaging components and thin-film recording head coils. To form such integrated circuitry or thin-film circuitry, a microelectronic device substrate may be utilized having a number of dielectric and conductive layers (multilayers) formed on and/or within the device substrate. The microelectronic device substrate may include a bare substrate or any number of constituent layers formed on a bare substrate.

In the broad practice of the present invention, a cobalt-containing layer, preferably a metallic cobalt thin film, may be formed on a microelectronic device substrate using the novel cobalt (II) precursor when low resistivity, increased interfacial mechanical strength, and increased adhesion between a copper-containing layer and other layers of the device, is preferred. In a particularly preferred embodiment, the microelectronic device substrate comprises at least one stack including an insulating layer such as an ILD layer, a barrier layer, a cobalt-containing adhesion layer, and a copper-containing metallization layer. Preferably, the cobalt-containing adhesion layer is about 10 Å to about 100 Å in thickness.

As a further variation, when cobalt alloy compositions are to be deposited on the substrate, the cobalt precursor formulation may contain or be mixed with other metal source reagent materials, or such other reagent materials may be separately vaporized and introduced to the deposition chamber.

The deposition of cobalt thin films to enhance adhesion of the copper layers to the barrier layers (e.g., formed of TiN or TaN) is achieved using the process and precursors of the present invention. The conformality of the deposited cobalt film is practically achievable through CVD or ALD techniques and permits the use of the preferred CVD or ALD techniques for the deposition of the copper seed-layer thereon. The liquid delivery approach of the present invention, including “flash” vaporization and the use of cobalt precursor chemistry as herein disclosed, enable next-generation device geometries and dimensions to be attained, e.g., a conformal vertical interconnect of 65 nanometer linewidths. Moreover, the adhesion layers minimize copper layer delamination during subsequent CMP processes. Thus, the approach of the present invention affords a viable pathway to future generation devices, and embodies a substantial advance in the art.

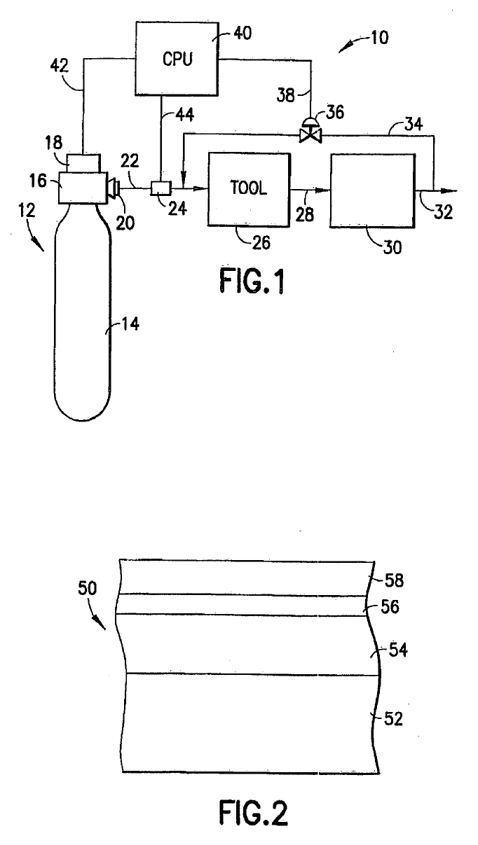

FIG. 1 is a schematic representation of a process system 10 according to one embodiment of the invention, in which a cobalt precursor composition of the invention is supplied from a precursor source package 12 to a semiconductor manufacturing tool 26, and the effluent from the tool is subjected to abatement/reclamation treatment in abatement/reclamation unit 30.

The precursor source package 12 includes a vessel 14 enclosing an interior volume that is leak-tightly sealed against the ambient environment of the vessel, being coupled to valve head 16 containing a valve element translatable between a fully closed and a fully opened position (not shown). The valve element in valve head 16 is coupled to valve actuator 18. Valve actuator 18 is arranged to modulate the valve element in the valve head 16, for selective dispensing of cobalt precursor from the vessel.

The vessel for such purpose may contain in the interior volume a precursor storage medium, in which the precursor is stored and from which the precursor is released under dispensing conditions. The precursor storage medium in one embodiment comprises a solid-phase physical adsorbent medium, having sorptive affinity for the precursor, whereby the precursor is reversibly adsorbed on the physical adsorbent medium. Such physical adsorbent medium can be of any suitable type having suitable loading capacity for the precursor.

In one embodiment, the physical adsorbent comprises a porous carbon material, which may be in the form of beads, pellets, particles or other divided or discontinuous form of material, constituting a bed of the storage medium in the interior volume of the vessel. Alternatively, the carbon adsorbent may be in a monolithic form, e.g., blocks, bricks, discs, rods, cylinders, or other suitable bulk form articles.

In another embodiment, the physical adsorbent material may comprise a molecular sieve, aluminosilicate, macroreticulate polymer, or other suitable material having appropriate porosity and pore size characteristics, surface area, etc. providing appropriate storage and dispensing capability for the cobalt precursor.

The precursor source package 12 in another embodiment contains the cobalt precursor in a solid form in the interior volume of the vessel, in which the cobalt precursor is supported on an enhanced surface area within the vessel. Such an enhanced surface area may include structures therein, such as trays, as described in U.S. Pat. No. 6,921,062, or porous inert foam inserts, e.g. of anodized aluminum or nickel foam, stainless steel, nickel, bronze, etc., to provide a consistent rate of evaporation of the precursor material to provide sufficient vapor pressure for the dispensing and ionizing steps of the associated implantation process. Where trays are utilized, the source composition may be supported on surfaces of trays disposed in the interior volume of the vessel, with the trays having flow passage conduits associated therewith, for flow of vapor upwardly in the vessel to the valve head assembly, for dispensing in use of the vessel.

The solid source composition can be coated on interior surfaces in the interior volume of the vessel, e.g., on the surfaces of the trays and conduits described above. Such coating may be effected by introduction of the source composition into the vessel in a vapor form from which the solid source composition is condensed in a film on the surfaces in the vessel. Alternatively, the source composition solid may be dissolved or suspended in a solvent medium and deposited on surfaces in the interior volume of the vessel by solvent evaporation. For such purpose, the vessel may contain substrate articles or elements that provide additional surface area in the vessel for support of the source composition film thereon.

As a still further alternative, the cobalt precursor as a solid source composition may be provided in granular or finely divided form, which is poured into the vessel to be retained on the top supporting surfaces of the respective trays therein.

In use, the vessel containing the cobalt precursor as a solid source material is heated, so that solid source composition in the vessel is at least partially volatilized to provide source composition vapor, for flow into the feed line 22 to the tool 26.

In lieu of solid delivery of the source composition, the source composition may be provided in a solvent medium, forming a solution or suspension. Such source composition-containing solvent composition then may be delivered by liquid delivery and flash vaporized to produce a source composition vapor. The source composition vapor is contacted with a substrate under deposition conditions, to deposit the cobalt on the substrate as a film thereon.

Suitable solvents for such purpose, in specific embodiments, can include, but are not limited to, C₃-C₁₂ alkanes, C₂-C₁₂ ethers, C₆-C₁₂ aromatics, C₇-C₁₆ arylalkanes, C₁₀-C₂₅ arylcyloalkanes, and further alkyl-substituted forms of such aromatic, arylalkane and arylcyloalkane species. Where the solvent is a further alkyl-substituted form of one of the above, and possesses multiple alkyl substituents, those substituents may be the same as or different from one another and each is independently selected from C₁-C₈ alkyl.

In a specific embodiment the solvent medium is selected from the group consisting of alkanes, alkyl-substituted benzene compounds, benzocyclohexane (tetralin), alkyl-substituted benzocyclohexane and ethers. In another embodiment, the solvent medium comprises a solvent species selected from the group consisting of tetrahydrofuran, xylene, 1,4-tertbutyltoluene, 1,3-diisopropylbenzene, tetralin, dimethyltetralin, octane and decane. In yet another embodiment the solvent medium comprises a solvent species selected from the group consisting of xylene, 1,4-tertbutyltoluene, 1,3-diisopropylbenzene, tetralin, dimethyltetralin and other alkyl-substituted aromatic solvents.

In one embodiment, the source composition is dissolved in an ionic liquid medium in the vessel of the cobalt precursor source package, and cobalt precursor vapor is withdrawn from the ionic liquid solution under dispensing conditions.

Supply vessels for cobalt precursor delivery may be of widely varying type, and may employ vessels such as those commercially available from ATMI, Inc. (Danbury, Conn.) under the trademarks SDS, SAGE, VAC, VACSorb, and ProE-Vap, as may be appropriate in a given storage and dispensing application for a particular source composition of the invention.

Referring again to FIG. 1, the valve head 16 of the precursor source package 12 features a discharge port 20 that is coupled to discharge line 22. The cobalt precursor discharged from the vessel and valve head passages into discharge line 22 is monitored by monitoring unit 24, which senses flow rate, concentration, or other appropriate characteristic of the cobalt precursor, and responsively generates an output that is transmitted in signal transmission line 44 to CPU 40.

The cobalt precursor flows in line 22 to the semiconductor manufacturing tool 26, for utilization therein. The semiconductor manufacturing tool 26 may be of any suitable type in which the cobalt precursor is employed in the fabrication of a microelectronic device. For example, the semiconductor manufacturing tool may include an ion implanter, a chemical vapor deposition chamber, an atomic layer deposition apparatus, or other tool. In one preferred embodiment, the tool 26 comprises a vapor deposition system, in which cobalt is deposited on a substrate of a microelectronic device. Methods of deposition may include, but are not limited to, chemical vapor deposition, molecular beam epitaxy, diffusion, rapid thermal processing, atomic layer deposition (ALD), and pulsed laser ablation and deposition (PLAD).

In the embodiment shown, the utilization of the cobalt precursor in tool 26 results in the generation of an effluent that is discharged from the tool into effluent line 28, passing to abatement/reclamation unit 30. The abatement/reclamation unit may be constructed and arranged for treatment of the effluent to remove toxic or otherwise undesirable components from such effluent, to produce a contaminant-reduced final effluent that is discharged from the abatement/reclamation unit 30 in vent line 32. Alternatively, the abatement/reclamation unit may be constructive and arranged for reclamation of precursor from the effluent, to produce a precursor-enriched stream discharged from the abatement/reclamation unit in vent line 32, with recycle of the precursor-enriched stream in recirculation line 34 containing flow control valve 36, to line 22 for combination with the precursor from the precursor source package 12 being fed to the tool 26.

The CPU 40 may comprise a microprocessor, programmable logic controller, general-purpose programmable computer, or other computational unit that is adapted to receive a signal in signal transmission line 44 from the monitoring unit 24, and to responsively output control signals for process control of the system 10. In the embodiment shown in FIG. 1, the CPU 40 is coupled via signal transmission line 38 to flow control valve 36 in the recirculation line 34, and the CPU is coupled via signal transmission line 42 to the valve actuator 18 for modulation of the valve in the valve head 16. By such arrangement, the CPU controls the recycle rate of precursor-enriched gas in line 34 to the tool 26, and controls the supply of cobalt precursor from the precursor source package 12 to the tool 26, to achieve optimal operation of the system 10, in the use of the cobalt precursor.

FIG. 2 is a schematic representation of a microelectronic device structure 50 comprising a cobalt barrier layer 56 deposited on a dielectric layer 54 on a substrate 52, wherein the cobalt barrier layer 56 has a copper layer 58 deposited thereon, e.g., by a copper damascene process. In such device structure, the cobalt barrier layer serves to minimize any undesired migration of copper from the copper layer 58 into the dielectric layer 54.

The cobalt layer 56 in such microelectronic device structure can be deposited by atomic layer deposition or other vapor deposition technique, at an appropriate thickness providing a suitable diffusional barrier against copper migration.

It will be recognized that the cobalt precursors of the invention can be variously employed in the manufacture of microelectronic devices of widely different types, and that the process conditions of temperature, pressure, flow rate and concentration of the cobalt precursor in such applications can be readily determined, within the skill of the art, based on the disclosure herein and empirical identification of suitable ranges and optimal values for such process conditions.

While the invention has been described herein with reference to various specific embodiments, it will be appreciated that the invention is not thus limited, and extends to and encompasses various other modifications and embodiments, as will be appreciated by those ordinarily skilled in the art. Accordingly, the invention is intended to be broadly construed and interpreted, in accordance with the ensuing claims.

1.-108. (canceled)

109. A cobalt precursor composition comprising a cobalt precursor selected from the group consisting of:
(a) aminidates, guanidates and isoureates of the formula:
R⁴ₙCo[R¹NC(R³)NR²]_{OX-n}
wherein:
R¹, R², R³ and R⁴ may be the same as or different from one another and are independently selected from the group consisting of hydrogen, halogen, C₁-C₆ alkyl, C₁-C₆ alkoxy, C₃-C₇ cycloalkyl, C₆-C₁₀ aryl, cyanide, boride, arylalkyl, aryloxy (ArO), amino, silyl, amide, and hydrocarbyl derivatives of silyl groups,
OX is the oxidation state of cobalt, and
n is an integer having a value of from 0 to OX;
(b) tetra-alkyl guanidates of the formula
R⁴ₙCo[(R¹R²)NC(NR³R⁵)N)]_{OX-n}
wherein:
R¹, R², R³, R⁴ and R⁵ may be the same as or different from one another and are independently selected from the group consisting of hydrogen, halogen, C₁-C₆ alkyl, C₁-C₆ alkoxy, C₃-C₇ cycloalkyl, C₆-C₁₀ aryl, cyanide, boride, arylalkyl, aryloxy (ArO), amino, silyl, amide, and hydrocarbyl derivatives of silyl groups,
OX is the oxidation state of cobalt, and
n is an integer having a value of from 0 to OX; and
(c) beta-diketonates, diketoiminates, and diketiiminates, of the formulae:
[OC(R¹)C(R³)C(R²)O]_{OX-n}Co(R⁴)ₙ
[OC(R⁵)C(R³)C(R²)N(R¹)]_{OX-n}Co(R⁴)ₙ
[R⁶NC(R⁵)C(R³)C(R²)N(R¹)]_{OX-n}Co(R⁴)ₙ
[(R¹)OC(═O)C(R³)C(R²)S]_{OX-n}Co(R⁴)ₙ
wherein:
R¹, R², R³, R⁴, R⁵ and R⁶ may be the same as or different from one another and are independently selected from the group consisting of hydrogen, halogen, C₁-C₆ alkyl, C₁-C₆ alkoxy, C₃-C₇ cycloalkyl, C₆-C₁₀ aryl, cyanide, boride, arylalkyl, aryloxy (ArO), amino, silyl, amide, and hydrocarbyl derivatives of silyl groups,
OX is the oxidation state of cobalt, and
n is an integer having a value of from 0 to OX.

110. The cobalt precursor composition of claim 109, comprising a cobalt precursor selected from the group consisting of (a) aminidates, guanidates and isoureates.

111. The cobalt precursor composition of claim 109, comprising a cobalt precursor selected from the group consisting of (b) tetra-alkyl guanidates.

112. The cobalt precursor composition of claim 109, comprising a cobalt precursor selected from the group consisting of (d) beta-diketonates, diketoiminates, and diketiiminates.

113. The cobalt precursor composition of claim 109, further comprising a solvent or diluent for the cobalt precursor.

114. The cobalt precursor composition of claim 113, wherein said solvent or diluent comprises an organic solvent selected from the group consisting of alkane, aryl, amine, and imine solvents.

115. The cobalt precursor composition of claim 113, wherein said solvent or diluent comprises a solvent selected from the group consisting of hexane, heptane, octane, pentane, benzene, toluene, and dimethylformamide.

116. A method of depositing cobalt on a microelectronic device substrate, comprising:
(i) volatilizing a cobalt precursor composition as claimed in claim 109; and
(ii) contacting the volatilized cobalt precursor with the microelectronic device substrate under elevated temperature vapor deposition conditions to deposit cobalt on said substrate.

117. The method of claim 116, wherein the cobalt is deposited under chemical vapor deposition conditions.

118. The method of claim 116, wherein the cobalt is deposited under atomic layer deposition conditions.

119. The method of claim 116, wherein the microelectronic device substrate comprises a barrier layer material comprising a compound selected from the group consisting of titanium nitride, titanium silicide, tantalum nitride, tantalum silicide, tantalum silicon nitrides, niobium nitride, niobium silicon nitride, tungsten nitride, tungsten silicide, and ruthenium.

120. The method of claim 116, further comprising depositing a copper seed-layer directly on the deposited cobalt.

121. The method of claim 116, wherein the volatilized cobalt precursor is contacted with the microelectronic device substrate in the presence of a co-reactant comprising a species selected from the group consisting of hydrogen, ammonia, amides, diborane, alkenes, alkynes, silanes, boranes, amines, imines, carbon monoxide, and hydrogen transferring agents.

122. The method of claim 116, wherein the volatilized cobalt precursor is contacted with the microelectronic device substrate in the presence of an inert gas.

123. The method of claim 121, wherein the precursor and co-reactant are concurrently contacted with the microelectronic device substrate.

124. The method of claim 121, wherein the precursor and co-reactant are separated in a pulse train, in their contact with the microelectronic device substrate, optionally further comprising a pulse purge between the precursor contact with the microelectronic device substrate and the co-reactant contact with the microelectronic device substrate.

125. The method of claim 121, wherein the co-reactant comprises tetralin.

126. A method of manufacturing a microelectronic device, comprising delivery of a cobalt precursor composition as claimed in claim 109, to a microelectronic device manufacturing tool.

127. A precursor source package comprising a vessel containing a cobalt precursor composition as claimed in claim 109, and a dispensing assembly coupled with the vessel and adapted for dispensing the cobalt precursor composition from the vessel.

128. A cobalt precursor compound comprising a cobalt species selected from the group consisting of:
(a) 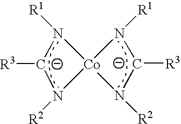
wherein R₁, R₂, and R₃ may be the same as or different from one another and are independently selected from the group consisting of hydrogen, halogen, C₁-C₆ alkyl, C₁-C₆ alkoxy, C₃-C₇ cycloalkyl, cyanide, boride, aryl, aryloxy (ArO), amino and hydrocarbyl derivatives of silyl groups, with the proviso that when each of R¹ and R² is independently either isopropyl or t-butyl, both R³ are not methyl;
(b) 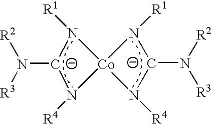
where R₁ to R₆ are the same as or different from one another and are independently selected from the group consisting of hydrogen, C₁-C₄ alkyl, C₁-C₆ alkoxy, and hydrocarbyl derivatives of silyl groups; and
(c) 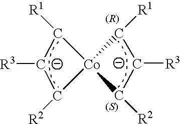
where R₁, R₂, and R₃ may be the same as or different from one another and are independently selected from the group consisting of hydrogen, halogen, C₁-C₆ alkyl, C₁-C₆ alkoxy, C₃-C₇ cycloalkyl, cyanide, boride, aryl, aryloxy (ArO), hydrocarbyl derivatives of silyl groups, and NR⁴R⁵, wherein R⁴ and R⁵ may be the same as or different from one another and are independently selected from the group consisting of H, C₁-C₆ alkyl, C₃-C₇ cycloalkyl, aryl, amino and hydrocarbyl derivatives of silyl groups, with the proviso that when each of R¹ and R² is trimethylsilyl, both R³ are not hydrogen.
